(19) United States
(12) Patent Application Publication
(10) Pub. No.: US 2021/0335716 A1
(43) Pub. Date: Oct. 28, 2021

(54) DISPLAY SCREEN

(71) Applicants: Jilong Li, Shenzhen (CN); Yue WANG, Shenzhen (CN)

(72) Inventors: Jilong Li, Shenzhen (CN); Yue WANG, Shenzhen (CN)

(21) Appl. No.: 16/626,545

(22) PCT Filed: Nov. 12, 2019
(86) PCT No.: PCT/CN2019/117484

§ 371 Date: Dec. 25, 2019

(30) Foreign Application Priority Data
Feb. 9, 2019 (CN) 201910821337.1

(51) Int. Cl. H01L 23/538; H01L 25/18; H01L 23/60

(52) U.S. Cl. CPC H01L 23/5386; H01L 25/18; G02F 1/13452; H01L 23/5387; H01L 23/60

(57) ABSTRACT

A display screen comprising a display panel, at least one control chip, and a chip on film (COF) disposed corresponding to the at least one control chip, the COF is used to connect the display panel and the at least one control chip. Each control chip comprises a plurality of connection points electrically connected to a plurality of connection pins on the COF. Two of the plurality of connection points are provided with a lead end respectively, and the two lead ends are used for connecting to an external test circuit.

### BACKGROUND OF INVENTION

### Field of Invention

The present invention relates to the field of electronic display, and in particular, to a display screen.

### Description of Prior Art

Current display screens typically include a display panel and a control chip. Generally, in order to reduce an area occupied by a non-display region of the display screen and increase a screen ratio of the display screen, the display panel and the control chip are electrically connected by a chip on film (COF). A carrier of the COF is a flexible film. With a bendable nature of the COF, the control chip can be placed on the non-display region of the display screen, thereby reducing the area occupied by the non-display region of the display screen.

### Technical Problems

The current design places the control chip on the non-display region of the display screen; thus, the COF needs to be bent. Because circuits on the COF are densely disposed on a surface of the flexible film, and a thickness of the flexible film is small; therefore, in order to protect the circuit on a connection surface, a side on which the COF is provided with a circuit is bent toward inside, and the side where the COF is not provided with the circuit is outward.

Although this arrangement can protect the COF, at the same time, when testing the COF circuit, it is necessary to open the control chip together with the COF. COF's area is small, and its circuit density is high. Frequent flipping for test would break off the circuit. At the same time, test points used for testing are easily shorted to the adjacent circuit, causing COF damage. In addition, the flip test may damage the connection between the COF and the display panel, causing the COF and the display panel to fall off.

Therefore, it is necessary to improve the prior art.

### SUMMARY OF INVENTION

The present application provides a display screen to solve the technical problem that the existing COF structure is not conducive to testing.

In order to solve the above problems, the present application provides a display screen comprising a display panel, at least one control chip, and a chip on film (COF) disposed corresponding to the at least one control chip, the COF is used to connect the display panel and the at least one control chip;

wherein each control chip comprises a plurality of connection points electrically connected to a plurality of connection pins on the COF;

wherein two of the plurality of connection points are provided with a lead end respectively, and the two lead ends are used for connecting an external test circuit.

According to one aspect of the application, wherein each COF has a plurality of first connection pins electrically connected to the display panel and a plurality of second connection pins electrically connected to the control chip, wherein the plurality of second connection pins are in one-to-one correspondence with a plurality of connection points on the control chip.

According to one aspect of the application, wherein the plurality of second connection pins are connected in one-to-one correspondence with the sources of the plurality of thin film transistors in the COF.

According to one aspect of the application, wherein the plurality of second connection pins are arranged in parallel along a first direction, electrical signals connecting the two adjacent second connection pins are logically adjacent, wherein the first direction is parallel to one of a side edges of the display panel.

According to one aspect of the application, wherein the lead ends comprise a first lead end and a second lead end, wherein the first lead end and the second lead end are respectively disposed on two connection points, and electrical signals connected by the two connection points are logically adjacent.

According to one aspect of the application, wherein the first lead end is disposed at a first connection point disposed along the first direction, and the second end is disposed at a last connection point disposed along the first direction.

According to one aspect of the application, wherein the display screen further comprises a protective film covering the lead ends, wherein the protective film is an electrically insulating material.

According to one aspect of the application, wherein the protective film is an insulating paint.

According to one aspect of the application, wherein the display panel is a liquid crystal display panel.

According to one aspect of the application, wherein the display panel is an organic light emitting diode display pane.

Beneficial Effects

The present application transfers the test points used for chip on film (COF) testing from the COF to the corresponding control chip. Because a circuit trace density of the control chip is less than the trace density on the COF, a probability that the test point interferes with other portions of the circuit is reduced. Simultaneously, the test points are set on the control chip, traces can be directly connected from the control chip to the test chip without opening the COF, thereby avoiding a breakage of the traces caused by frequent flipping of the test, shedding risk of COF and display panel can also be decreased.

### BRIEF DESCRIPTION OF DRAWINGS

FIG. 1 is a structural diagram of a display screen in a specific embodiment of the present application.

FIG. 2 is a partially enlarged schematic view of the display screen of FIG. 1.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

The present application provides a display screen to solve the technical problem that the existing COF structure is not conducive to testing. The technical solution of the present application will be described in detail below with reference to the drawings.

The present application provides a display screen including a display panel 10, at least one control chip 30, and a chip on film (COF) 20 disposed corresponding to the at least one control chip 30, the COF 20 is used to connect to the display panel 10 and to the at least one control chip 30.

The display panel 10 in the present application can be a liquid crystal display panel, an organic light emitting diode display panel, or a quantum dot light emitting diode display panel. Regardless of the type of display panels, the technical solution in the present application can be adopted. In this embodiment, an organic light emitting diode display panel will be described as an example.

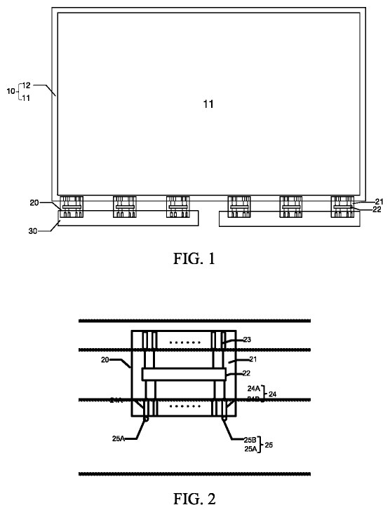

Referring to FIG. 1, FIG. 1 is a structural diagram of a display screen in an embodiment of the present application. The display panel 10 includes a display area 11 and a non-display area 12. The non-display area 12 surrounds the display area 11. The non-display area 12 is provided with a plurality of connection areas for electrically connecting to the COF 20. Generally, one display panel is correspondingly provided with a plurality of control chips 30, and each of the control chips 30 needs to be electrically connected to the display panel through a plurality of COF 20. In this embodiment, the number of the control chips 30 is two, and each of the control chips 30 is electrically connected to the display panel through three COF 20. It should be noted that the number of the COF 20 and the control chip 30 is only for explaining the present application, and should not be construed as limiting the present application.

Referring to FIG. 2, FIG. 2 is a partially enlarged schematic view of the display screen of FIG. 1, and FIG. 2 is a structural diagram of one of the COF 20. Each of the COF 20 includes a flexible film 21 and an integrated circuit chip 22 on the flexible film 21. The integrated circuit chip 22 is electrically connected to the display panel 10 through a plurality of first connection pins 23, and is electrically connected to the control chip 30 through a plurality of second connection pins 24.

In this embodiment, each of the COF 20 has a plurality of first connection pins 23 electrically connected to the display panel 10, and a plurality of second connection pins 24 electrically connected to the control chip 30. The plurality of second connection pins 24 are in one-to-one correspondence with a plurality of connection points 25 on the control chip 30.

In the present application, each of the control chips 30 includes a plurality of connection points 25 electrically connected to a plurality of second connection pins 24 on the COF 20, respectively. Two of the plurality of connection points 25 are respectively provided with lead ends on the connection points 25 for connecting to external test circuits. In the present application, the plurality of second connection pins 24 are connected in one-to-one correspondence with the sources of the plurality of thin film transistors in the COF 20.

Referring to FIG. 2, in the present application, the plurality of second connection pins 24 are arranged in parallel along a first direction, electrical signals connected by the two adjacent second connection pins 24 are logically adjacent, wherein the first direction is parallel to one of side edges of the display panel 10. The logically adjacent electrical signals refer to the logical correlation of two electrical signals. For example, an electrical signal is a level-transmitted signal. That is, an electrical signal connected to the first second connecting pin 24 disposed along the first direction is G(1). An electrical signal connected to the second connecting pin 24 disposed along the first direction is G(2). An electrical signal connected to the nth second connection pin 24 disposed in the first direction is G(n). Of course, the electrical signal may also be other electrical signals that logically have a bearing relationship.

In the present application, the lead end includes a first lead end 25A and a second lead end 25B, and the first lead end 25A and the second lead end 25B are respectively disposed at two connection points. Because it is necessary to test two electrical signals adjacent in logic when the COF is tested, the electrical signals connected by the two connection points corresponding to the first lead end 25A and the second lead end 25B are logically adjacent, for example, the electrical signal G(n) and the electrical signal G(n+1).

Referring to FIG. 2, in the present application, the first lead end 25A is disposed at a first connection point disposed along the first direction, and the second end 25B is disposed at a last connection point disposed along the first direction.

Since the electrical signals corresponding to the plurality of second connection pins 24 are logically adjacent, the first one and the second one of the plurality of electrical signals are logically adjacent. Meanwhile, because the plurality of second connection pins 24 are sequentially disposed in the first direction, the second connection pin and the the last connection pin are not only logically adjacent, but also has a greatest physical distance. The greater the physical distance between the test points, the easier it is to achieve cross-extraction when connected to the test circuit, thereby reducing difficulties in design and operation.

In the present application, the display screen further includes a protective film covering the first lead end 25A and the second lead end 25B. In order to achieve electrical connection, the first lead end 25A and the second lead end 25B are made of conductive metal. The lead ends made of metal easily attracts static electricity, and a large amount of static electricity concentrated on a surface of the exposed metal lead end will cause electrostatic breakdown and damage the panel. Therefore, the present application provides a protective film covering the first lead end 25A and the second lead end 25B. The protective film is made of an electrically insulating material, which can effectively avoid electrostatic concentration, thereby avoiding electrostatic breakdown. In this embodiment, the protective film is an insulating paint.

The present application transfers the test points used for COF testing from the COF to the corresponding control chip. Because a circuit trace density of the control chip is less than the trace density on the COF, a probability that the test point interferes with other portions of the circuit is reduced. Simultaneously, the test points are set on the control chip, so traces can be directly connected from the control chip to the test chip without opening the COF, thereby avoiding a breakage of the traces caused by frequent flipping of the test, and decreasing the shedding risk of COF and display panel.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. A display screen comprising a display panel, at least one control chip, and a chip on film (COF) disposed corresponding to the at least one control chip, the COF is used to connect the display panel and the at least one control chip;
wherein each control chip comprises a plurality of connection points electrically connected to a plurality of connection pins on the COF;
wherein two of the plurality of connection points are provided with a lead end respectively, and the two lead ends are used for connecting an external test circuit.

2. The display screen according to claim 1, wherein each COF has a plurality of first connection pins electrically connected to the display panel and a plurality of second connection pins electrically connected to the control chip, wherein the plurality of second connection pins are in one-to-one correspondence with a plurality of connection points on the control chip.

3. The display screen according to claim 2, wherein the plurality of second connection pins are connected in one-to-one correspondence with sources of the plurality of thin film transistors in the COF.

4. The display screen according to claim 3, wherein the plurality of second connection pins are arranged in parallel along a first direction, and electrical signals connected by the two adjacent second connection pins are logically adjacent, wherein the first direction is parallel to one of side edges of the display panel.

5. The display screen according to claim 4, wherein the lead ends comprise a first lead end and a second lead end, wherein the first lead end and the second lead end are respectively disposed on two connection points, and electrical signals connected by the two connection points are logically adjacent.

6. The display screen according to claim 5, wherein the first lead end is disposed at a first connection point disposed along the first direction, and the second lead end is disposed at a last connection point disposed along the first direction.

7. The display screen according to claim 1, wherein the display screen further comprises a protective film covering the lead ends, wherein the protective film is an electrically insulating material.

8. The display screen according to claim 7, wherein the protective film is an insulating paint.

9. The display screen according to claim 1, wherein the display panel is a liquid crystal display panel.

10. The display screen according to claim 1, wherein the display panel is an organic light emitting diode display panel.
